(19) United States
(12) Patent Application Publication
(10) Pub. No.: US 2018/0266992 A1
(43) Pub. Date: Sep. 20, 2018

(54) QUANTIFYING TUBING DEFECT SEVERITY

(71) Applicant: SCHLUMBERGER TECHNOLOGY CORPORATION, Sugar Land, TX (US)

(72) Inventors: Zhanke LIU, Sugar Land, TX (US); Shunfeng ZHENG, Katy, TX (US); Oscar RIVAS-DIAZ, Fulshear, TX (US); Loren HAUGLUND, Sugar Land, TX (US)

(21) Appl. No.: 15/534,709

(22) PCT Filed: Dec. 11, 2015
(86) PCT No.: PCT/US2015/065202

§ 371 Date: Jun. 9, 2017

(51) Int. Cl. G01N 27/82; G01R 33/10

(52) U.S. Cl. CPC G01N 27/82; G01R 33/10

(57) ABSTRACT

A technique facilitates examination of a tubing string which may comprise coiled tubing or other types of pipe. The technique involves evaluation of defect severity as it relates to tubing fatigue life reduction. A sensor may be positioned to monitor a pipe for a magnetic flux leakage signal indicating a defect in the pipe. The sensor outputs data on the magnetic flux leakage signal to a data processing system. The sensor data is used by the data processing system to identify the defect type via computer modeling, e.g. by utilizing a benchmark defect library, and to determine its relationship with respect to pipe fatigue life.

### CROSS-REFERENCE TO RELATED APPLICATION

The present document is based on and claims priority to U.S. Provisional Application Ser. No. 62/090,631 filed Dec. 11, 2014, incorporated herein by reference in its entirety.

### BACKGROUND

Coiled tubing technology has been used in an expanding range of applications since its introduction to the oil industry in the 1960s. The wide array of tools and technologies that can be used in cooperation with coiled tubing and the ability of coiled tubing to pass through completion tubulars makes the technology very versatile. A coiled tubing system may include surface pumping facilities, a coiled tubing string mounted on a reel, an injector head or other mechanism to convey the coiled tubing into and out of the wellbore, and a surface control apparatus at the wellhead. The coiled tubing may be deployed in wellbores to facilitate performance of well treatment and/or well intervention operations, e.g. operations comprising hydraulic fracturing, matrix acidizing, milling, perforating, coiled tubing drilling, or other downhole operations.

The use of coiled tubing in the oilfield regularly subjects the coiled tubing to severe cyclic plastic deformation. As a result, low cycle fatigue may be a major limiting factor with respect to the useful life (fatigue life) of the coiled tubing. Regular use of the coiled tubing also subjects the tubing to potential damage factors, such as mechanical damage due to surface equipment, corrosion due to storage, treating fluids or wellbore fluids, abrasion due to contact with downhole completions, and/or erosion due to flowing fluids. At least some of the coiled tubing failures are attributable to the defects, e.g. mechanical damage, fatigue, corrosion, and/or manufacturing defects. Coiled tubing inspection technologies are available, and some inspection technologies are based on detection of magnetic flux leakage as an indicator of defects. However, magnetic flux leakage systems often rely on alarm thresholds combined with human intervention which can limit the accuracy and usefulness in a variety of applications.

### SUMMARY

In general, the present disclosure provides a methodology and system for examining tubing which may comprise coiled tubing or other types of pipe. The technique involves evaluation of defect severity as it relates to tubing fatigue life reduction, e.g. coiled tubing fatigue life reduction. According to an embodiment, a sensor is positioned to monitor a pipe for a magnetic flux leakage signal indicating a defect in the pipe. The sensor outputs data on the magnetic flux leakage signal to a data processing system. The sensor data is used to identify the defect type via computer modeling, e.g. by utilizing a benchmark defect library, and to determine defect severity as an indicator of fatigue life with respect to coiled tubing or other pipe.

### BRIEF DESCRIPTION OF THE DRAWINGS

Certain embodiments will hereafter be described with reference to the accompanying drawings, wherein like reference numerals denote like elements. It should be understood, however, that the accompanying figures illustrate various implementations described herein and are not meant to limit the scope of various technologies described herein, and:

FIG. 1 is a schematic illustration of an example of a pipe defect assessment system for evaluating pipe, e.g. coiled tubing, according to an embodiment of the disclosure;

FIG. 2 is a schematic illustration of a processor-based system for evaluating sensor data obtained while evaluating pipe, according to an embodiment of the disclosure;

FIG. 3 is an illustration showing a defect disposed along a pipe, e.g. coiled tubing, according to an embodiment of the disclosure;

FIG. 4 is a diagrammatic representation of a magnetic flux leakage intensity signature based on sensor data obtained regarding the defect illustrated in FIG. 3, according to an embodiment of the disclosure;

FIG. 5 is an illustration showing another type of defect disposed along a pipe, e.g. coiled tubing, according to an embodiment of the disclosure;

FIG. 6 is a diagrammatic representation of a magnetic flux leakage intensity signature based on sensor data obtained regarding the defect illustrated in FIG. 5, according to an embodiment of the disclosure;

FIG. 7 is a diagrammatic representation of a plurality of defect library entries representing defects including defect library entries corresponding with “gouge” type defects, according to an embodiment of the disclosure;

FIG. 8 is an illustration of a defect with a relatively simple geometrical form, according to an embodiment of the disclosure;

FIG. 9 is an illustration of a defect with a relatively complex geometrical form, according to an embodiment of the disclosure;

FIG. 10 is a graphical representation of a correlation plot between magnetic flux leakage intensity and geometrical severity parameter while also showing an independence with respect to tubing wall thickness, according to an embodiment of the disclosure;

FIG. 11 is a graphical representation of magnetic flux leakage intensity versus fatigue life ratio, according to an embodiment of the disclosure;

FIG. 12 is an illustration of different types of defects used to validate computer modeling, according to an embodiment of the disclosure;

FIG. 13 is an illustration of another set of defects used to validate computer modeling, according to an embodiment of the disclosure;

FIG. 14 is a graphical representation of a fitted model for magnetic flux leakage based fatigue life ratio prediction compared with fatigue testing data, according to an embodiment of the disclosure; and

FIG. 15 is an illustration of a plurality of defects evaluated for severity using developed and validated correlations, according to an embodiment of the disclosure.

### DETAILED DESCRIPTION

In the following description, numerous details are set forth to provide an understanding of some illustrative embodiments of the present disclosure. However, it will be understood by those of ordinary skill in the art that the system and/or methodology may be practiced without these details and that numerous variations or modifications from the described embodiments may be possible.

The disclosure herein generally relates to a methodology and system for evaluating ferrous metal pipe, e.g. coiled tubing. The system and methodology may be used with pipe related to well site equipment including oilfield surface equipment, downhole assemblies, coiled tubing assemblies, and other well related equipment. In some applications, the coiled tubing or other pipe may be used in non-well related operations.

According to an embodiment, the methodology and system involve evaluation of defect severity as an indicator of pipe fatigue life reduction, e.g. coiled tubing fatigue life reduction. According to an embodiment, a sensor is positioned to monitor a pipe for a magnetic flux leakage signal indicating a defect in the pipe. The sensor outputs data on the magnetic flux leakage signal to a data processing system. The sensor data is used to identify the defect type via computer modeling and to determine its relationship with respect to coiled tubing fatigue life or the fatigue life of other types of pipe. In some applications, the computer modeling comprises utilization of a benchmark defect library which is used in determining the severity of the defect in a manner which corresponds to fatigue life.

Magnetic flux leakage based non-destructive evaluation (NDE) technology utilizes a magnetic field to magnetize the coiled tubing or other pipe made of ferrous metal. In areas of defects, e.g. material discontinuity, corrosion pit, mechanical damage, metal loss, the magnetic field leaks from the metal. Measurements of this magnetic flux leakage field is then used to infer the underlying defect in the pipe. In general, newer pipes may provide more readily detectable defects because the overall magnetic flux leakage signal tends to have a relatively low base signal due to the consistency of the pipe. With used coiled tubing or other pipe, however, numerous small defects may be located along the pipe due to interaction of the pipe with surface equipment, corrosion, or other defects resulting from use of the pipe. The numerous defects can create a relatively high base signal which renders determination of useful information regarding the defect more difficult. However, the technique described herein improves the detection and evaluation of defects for both new and used pipe, e.g. coiled tubing.

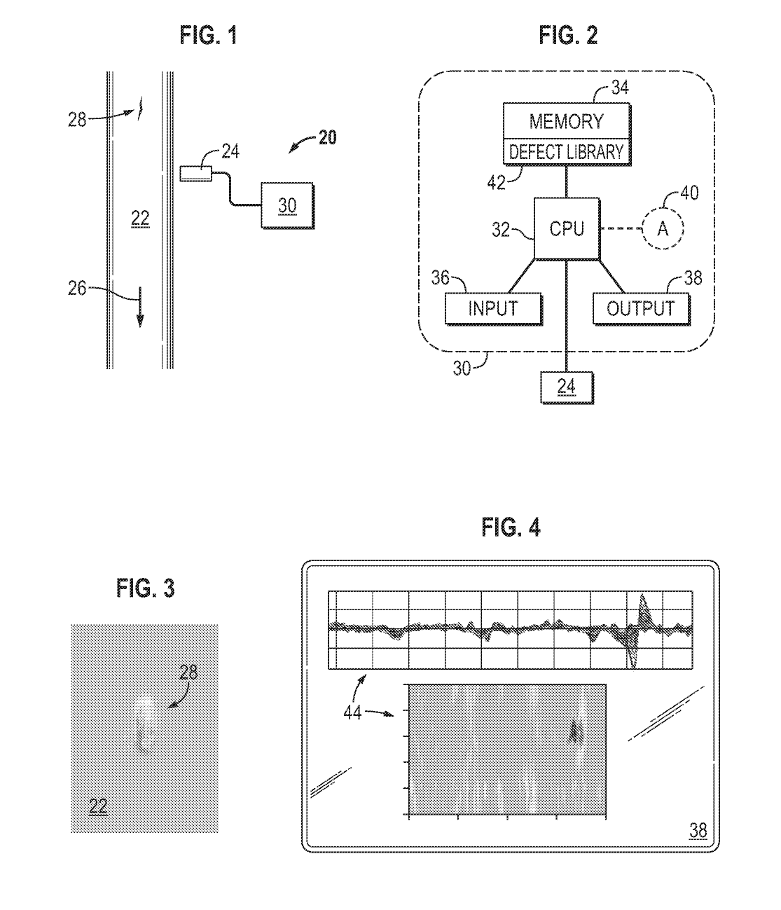

Referring generally to FIG. 1, an example of a pipe defect assessment system 20 for evaluating pipe 22, e.g. jointed pipe or coiled tubing, is illustrated. It should be noted that the embodiments described herein may be employed in well or non-well related applications. Additionally, the pipe defect assessment system 20 may comprise a variety of pipe support systems, pipe delivery systems, sensor arrangements, local and/or remote processing systems, data evaluation algorithms, models, and/or other software programs, as well as other components arranged in various configurations depending on the parameters of a pipe damage assessment application.

In FIG. 1, an embodiment of the pipe defect evaluation system 20 is illustrated as moving pipe 22 past an appropriate sensor or sensors 24. In embodiments described herein, the sensor or sensors 24 may comprise a magnetic field generated by, in a non-limiting embodiment, one or a plurality of permanent magnets, or coils, and magnetic flux leakage (MFL) sensors which monitor magnetic flux leakage. The relative movement of pipe 22 is indicated by arrow 26, however some embodiments may be constructed to move the sensor or sensors 24 along a stationary pipe 22. Additionally, both the pipe 22 and the sensor(s) 24 may be moved relative to each other.

Each sensor 24 is positioned to monitor for the presence of a magnetic flux leakage signal associated with a defect 28 and to output sensor data to a data processing system 30. The signals provided by sensor 24 change upon detection of the differing magnetic flux leakage signal associated with the defect or defects 28. The changes in that sensor data can be processed via data processing system 30 to, for example, quantify defect severity which can then be used to determine a fatigue life of the coiled tubing or other pipe.

The presence of a defect on coiled tubing affects its mechanical integrity by, for example, reducing its tensile load capacity, reducing its pressure containment capacity, and reducing its fatigue life. The fatigue life may be diminished because the presence of a defect often acts as a stress riser which can lead to development of fatigue cracking in coiled tubing or other pipe. By utilizing sensor or sensors 24, magnetic flux leakage changes may be monitored to determine whether the magnetic flux leakage signal begins to indicate characteristics associated with the defect. The magnetic flux leakage signal data is relayed from the sensor 24 to the data processing system 30 for evaluation, as described in greater detail below.

In the example illustrated, sensor or sensors 24 detect magnetic flux leakage but the sensors 24 may be combined with other types of sensors positioned to help detect and analyze a desired defect or defects along pipe 22. In some embodiments sensor 24 may comprise a single sensor but sensor 24 also may comprise a plurality of sensors or sensor elements arranged longitudinally and/or circumferentially. In a specific embodiment, sensor 24 comprises a plurality of magnetic flux leakage sensing elements positioned to detect along the circumference of pipe 22 as pipe 22 and sensor(s) 24 are moved relative to each other. In various testing applications, pipe 22 is in the form of coiled tubing which moves relative to the sensor. In other applications, however, pipe 22 may comprise individual pipe joints which are moved relative to the sensor.

Data obtained by the sensor or sensors 24 is transmitted to processing system 30. The processing system 30 may be located in whole or in part at a well site, at a well testing facility, and/or at a remote location. After processing data from each sensor 24, the processing system 30 may be used to display or otherwise output results related to the detection and evaluation of magnetic flux leakage signal data corresponding with defect 28. The raw and/or processed data may be sent to other systems and other locations for further processing, analysis, and/or control operations.

Referring generally to FIG. 2, an example of processing system 30 is illustrated. In this example, processing system 30 is in the form of a computer-based system having a processor 32, such as a central processing unit (CPU). The processor 32 is coupled with sensor or sensors 24 and is operatively employed to intake magnetic flux leakage signal data related to defects 28 and then to process the data, e.g. run appropriate models and/or algorithms. For example, the data may be processed to find similar stored signal data correlated with fatigue life for that specific type of pipe 22 and defect 28. The processor 32 also may be operatively coupled with a memory 34, an input device 36, and an output device 38.

In some applications, processor 32 is used to run selected algorithms/models, e.g. comparisons with stored correlations, via a software module 40. The software module 40 may comprise, for example, algorithms employed in computer models to provide a methodology for evaluating defect severity and the corresponding coiled tubing fatigue life reduction as described in greater detail below. The methodology, e.g. workflow, described herein comprises identifying the defect type via computer modeling, e.g. operating processor 32 to utilize a benchmark defect library. Software module 40 may comprise many types of models, algorithms, and programs selected according to the types of sensors 24, environmental considerations, types of defects anticipated, and/or other parameters.

According to an embodiment, the methodology/workflow comprises establishing correlations between magnetic flux leakage intensity parameter and fatigue life ratio based on testing data. The magnetic flux leakage intensity parameter may be defined herein as a parameter based on a ratio of an amplitude of the MFL sensor signal for a specific defect divided by an amplitude of the MFL sensor signal for a standardized defect. An intermediate parameter or parameters, e.g. geometrical severity parameter, may be used to efficiently construct the magnetic flux leakage intensity and defect severity relationships. In embodiments described herein, the detrimental effects of mechanical defects may be fatigue life related. It should be noted that correlations between magnetic flux leakage intensity and fatigue life ratio may depend on, for example, material grades, pressure levels, defect types, and/or other parameters. The methodology/workflow also may comprise determining the detrimental effects of defects based on an identified defect type and on an established magnetic flux leakage intensity versus fatigue life ratio correlation for different material grades, pressure levels, and/or other parameters.

The effects of a pipe defect with respect to fatigue life often depends on the defect type. As described herein, a defect identification algorithm/software module 40 is used to automatically determine the type of underlying defect indicated by an abnormal magnetic flux leakage signal. According to an embodiment, the defect identification algorithm 40 utilizes a benchmark defect library 42 and may comprise or work in cooperation with a defect correlation algorithm. By way of example, the data associated with the defects 28 of benchmark defect library 42 may be stored in memory 34 and/or in another suitable data storage location.

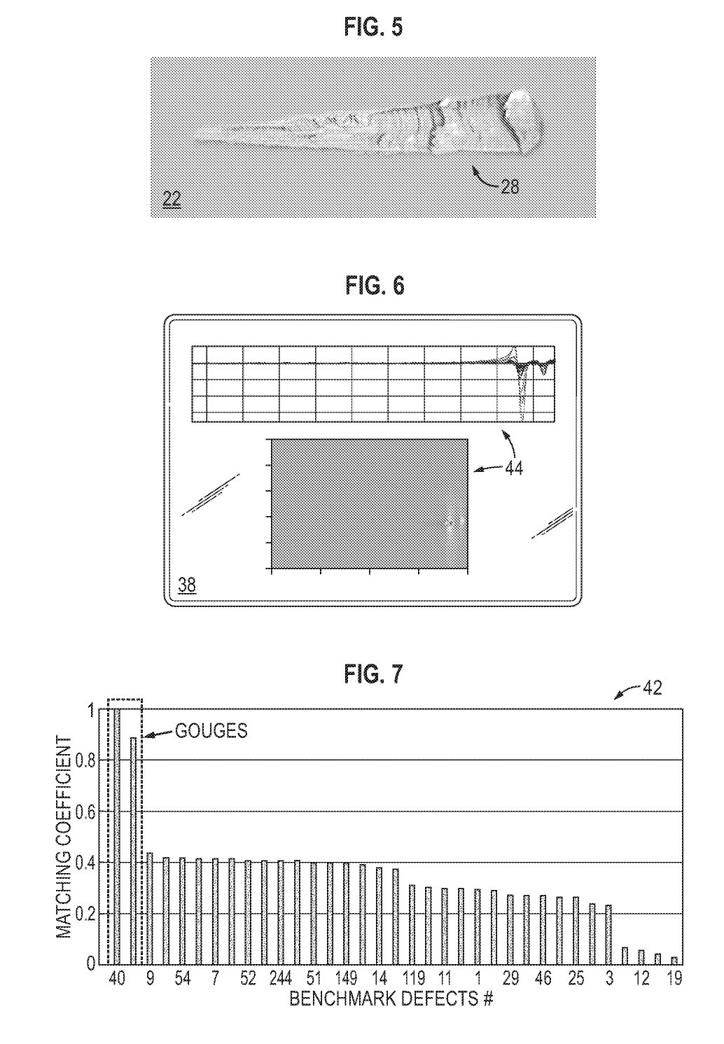

A benchmark defect library 42 may be established by collecting data on defects 28 via inspection of actual pipe, e.g. actual coiled tubing strings. These defects may occur during, for example, transportation and/or use of the coiled tubing or other pipe. Each defect entry in the benchmark defect library 42 may include selected attributes, e.g. a defect photo and a corresponding magnetic flux leakage signal or “defect signature” as illustrated in FIGS. 3-6. For example, FIG. 3 shows a photo of one type of defect 28 disposed in coiled tubing 22 and FIG. 4 illustrates the corresponding magnetic flux leakage signature 44 associated with that defect. Similarly, FIG. 5 shows a photo of another type of defect 28 disposed in coiled tubing 22 and FIG. 6 illustrates the corresponding magnetic flux leakage signature 44 associated with that defect. The magnetic flux leakage signatures 44 show a magnetic flux leakage intensity at the defect location that may be displayed on output device 38, e.g. a computer display screen.

It should be noted the defect signatures 44 include the high-resolution magnetic flux leakage signals around the defect 28. The high-resolution magnetic flux leakage signals contain magnetic flux leakage data from each sensor 24. According to an example, a plurality of sensors 24 is disposed adjacent coiled tubing 22. Each sensor 24, e.g. probe, may be arranged circumferentially around the coiled tubing 22. The magnetic flux leakage signature may contain these sensor signals obtained over a suitable axial distance along the tubing, e.g. about 1 ft, around the defect. The benchmark defect library 42 may be established with a predetermined number of defect entries encompassing different types of defects 28 and/or different defect orientations. For example, the predetermined number of defect entries may be in the hundreds of entries, e.g. 100-800 entries, or more. Additionally, the types of defects 28 may comprise gouges, dents, cuts, corrosion pits, weld anomalies, or other defect types. Similarly, the defects 28 may have a variety of different orientations, e.g. longitudinal orientations, transverse orientations, slanted orientations, or other orientations.

Once the benchmark defect library 42 is established, the defect identification algorithm 40 is utilized in detecting and identifying the potential defect. For example, when a defect 28 is detected by sensor or sensors 24, the data is sent to processing system 30 and processed according to the defect identification algorithm 40. The defect identification algorithm 40 utilizes the data obtained via the corresponding magnetic flux leakage signal to calculate a matching coefficient. The matching coefficient represents the level of similarity between the corresponding magnetic flux leakage signal associated with the defect 28 and entries that have been recorded in the benchmark defect library 42.

By way of example, a magnetic flux leakage signal corresponding with a “gouge” defect may be correlated via the algorithm with entries in the benchmark defect library 42. Defect library entries with high-ranking matching coefficients are selected as represented graphically in FIG. 7. In the specific example, two defect entries from the benchmark defect library 42 have a high-ranking matching coefficient with respect to the “gouge” defect detected via magnetic flux leakage sensor(s) 24. By choosing an appropriate correlation coefficient threshold, the type of defect 28 can be identified based on the level or rank of the matching coefficient when compared to entries in the benchmark defect library 42 via processing system 30.

The processing system 30 and algorithm 40 also may be used in performing defect severity evaluation which may comprise geometrical measurement. Mechanical damage of various types have an impact on the fatigue life of coiled tubing or other types of pipe. In some applications, algorithm 40 and/or a related algorithm may be used in computer modeling for quantifying fatigue life reduction due to mechanical defects of a particular geometrical type. Such computer modeling may utilize quantitative geometrical information, e.g. defect length, width, depth, and/or shape. A geometrical severity parameter may be developed based on such geometrical information. Through testing, strong correlations have been established between the geometrical severity parameter and fatigue life as recited in Christian, A. and Tipton, S. M. 2009. Statistical Analysis of Coiled Tubing Fatigue Data. Presented at the SPE/ICoTA Coiled Tubing and Well Intervention Conference and Exhibition, The Woodlands, Tex., USA, 31 March-1 April. SPE-121457-MS, incorporated by reference herein in its entirety.

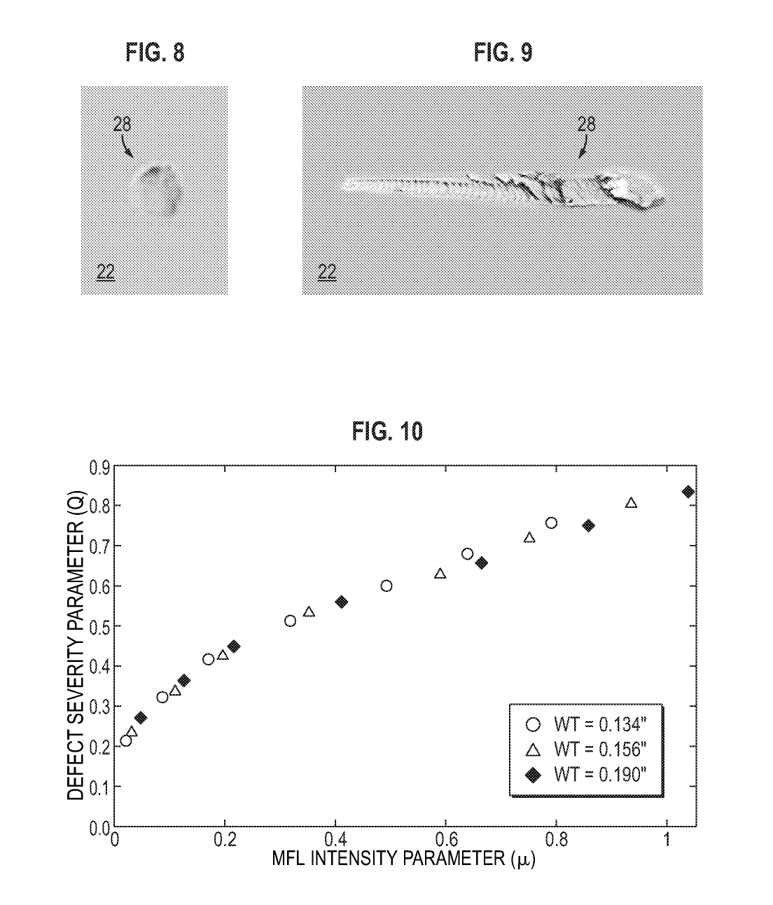

However, difficulties may arise in the quantitative determination of defect geometries. As illustrated in FIGS. 8 and 9, for example, defects 28 may have very different geometries. In the example illustrated in FIG. 8, measurements of defect depth, length, and width are relatively easy due to a simple geometry. However, the defect illustrated in FIG. 9 provides a complex topology which creates substantial challenges with respect to obtaining useful geometrical measurements. Due to its complexity, such measurements tend to be operator-dependent and error-prone. Different inspectors may come up with significantly different measurement results; inexperienced testers may get totally wrong results if not following guidelines correctly. Additionally, such measurement activities usually require the operations come to a stop so that a dedicated inspector may perform spot measurements. Such stopping might be possible during yard inspection; it's often difficult if at all possible during field jobs. Even during a yard inspection, it quickly becomes unacceptable if frequent stops are required to accommodate defect geometry measurements. Last but not least, certain defects such as corrosion pits may exist inside the pipe which are inaccessible for defect geometry determination.

The methodology described herein, however, employs magnetic flux leakage measurements for determining geometrical parameters of defects automatically without resorting to manual measurements. The correlation between magnetic flux leakage intensity and geometrical severity was established by using a large number of benchmark defects which were machined with accurate, known geometries, e.g. known length, width, depth, and shape. The benchmark defects were selected so the resulting geometrical severity parameters would cover a wide range of defects that can be expected to occur in the field. The results were used to create the benchmark defect library 42.

Additionally, the experiments were performed so that sensitivity with respect to tubing wall thickness, outside diameter, material grade, and other parameters could be studied. Results of the testing, illustrated graphically in FIG. 10, show that the correlation between magnetic flux leakage intensity and geometrical severity parameter is practically independent of tubing diameter, wall thickness, and material grade. In FIG. 10, a correlation plot between magnetic flux intensity (μ) and geometrical severity parameter (Q) is illustrated and shows good correlation independent of tubing wall thickness. As shown, the correlation plots for coiled tubing 22 with wall thicknesses of 0.134 inch, 0.156 inch, and 0.190 inch are very similar.

With the known correlation between magnetic flux leakage intensity (μ) and geometrical severity parameter (Q), as illustrated in FIG. 10, and the known correlation (established through jointed industrial research for example) between geometrical severity parameter (Q) and fatigue life ratio (ϕ), a further correlation may be established between magnetic flux leakage intensity (μ) and fatigue life ratio (ϕ). Notice that the magnetic flux leakage intensity parameter is directly proportional to the measured MFL signal level and distribution. In an embodiment, a method of defining the MFL intensity parameter is using maximum MFL value normalized by an MFL threshold value. The geometrical severity parameter may be a function of the defect geometry and type. There exists a commonly adopted definition in open literature for this parameter Q, as noted in the Christian and Tipton publication noted hereinabove. The fatigue life ratio (ϕ) is defined as the fatigue life of defected pipe over the fatigue life of non-defected pipe. The fatigue life ratio is bounded by 1 (lowest severity corresponding to pipes free of defects), and 0 (highest severity, corresponding to pipes with defects that are severe enough to reduce the fatigue life to zero).

### EXAMPLES

The correlations may be dependent on material grades and differential pressure to which the coiled tubing 22 or other pipe is subjected. In FIG. 11, a graphical example is provided to illustrate a correlation between magnetic flux leakage intensity and fatigue life ratio for a specific coiled tubing material grade. In this example, the pipe was a 90 ksi material grade pipe subjected to low pressure (7% yield) fatigue cycles. Similar correlations for other material grades and pressure levels may be established and stored in, for example, memory 34. The correlations may then be used by processing system 30 in determining automatic estimates of fatigue life for a given pipe 22 with a given defect 28 detected according to its magnetic flux leakage signature 44. The graph in FIG. 11 illustrates the accumulation of sample data 46 based on testing of pipe, e.g. coiled tubing, 22. Curve fitting of the data points 46 is then used to establish a fitted curve 48 which serves as part of the computer model/algorithm 40 that determines the detrimental effects of defects on fatigue life based on the correlation between magnetic flux leakage intensity and fatigue life ratio, which can then be used in determining fatigue life according to validated relationships based on test results as discussed herein.

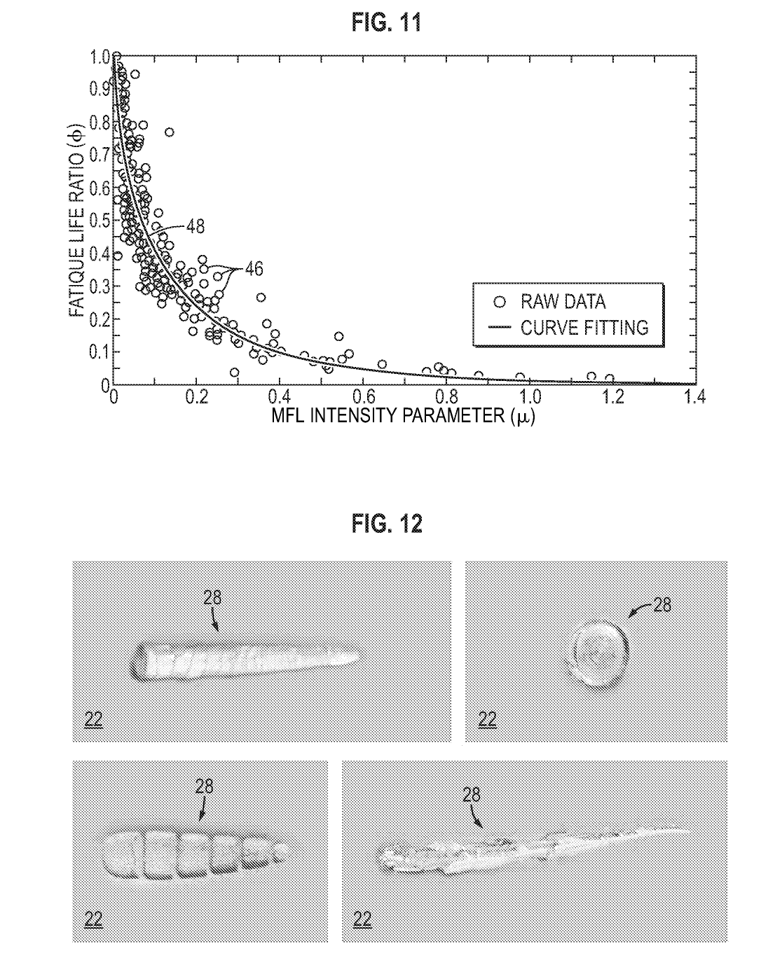

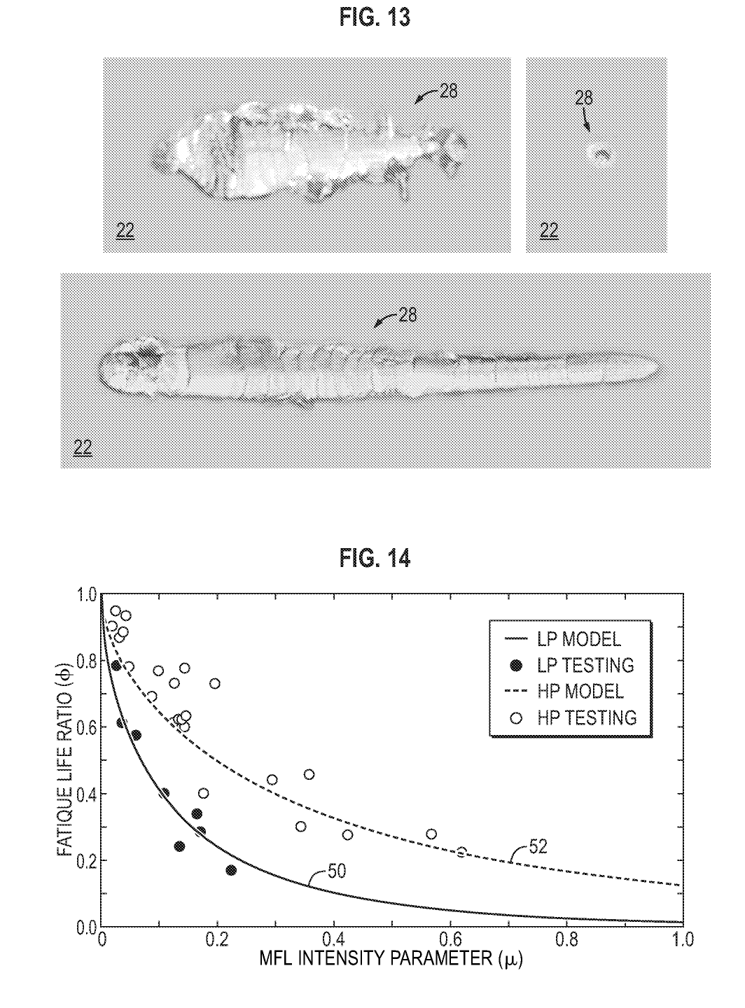

To validate the correlations described above between magnetic flux leakage intensity and fatigue life ratio as it impacts fatigue life of pipe 22, e.g. coiled tubing, actual fatigue testing was performed in the example. The fatigue testing was performed on a range of pipe samples with various defects 28 and under different pressure conditions. A number of pipe samples with imposed defects were fatigue tested at both low and high pressure levels until failure. Examples of the imposed defects 28 used during testing to validate the correlations are illustrated in FIGS. 12 and 13.

During validation, each of the pipes with imposed defects 28 was scanned using magnetic flux leakage inspection sensors 24 to obtain magnetic flux leakage intensity signatures 44 associated with the imposed defects 28 prior to fatigue testing. Then, the pipes with defects were tested with a fatigue machine to obtain the actual remaining fatigue life. Pipes of the same grade and batch without defects also were tested under corresponding pressure conditions to obtain baseline fatigue life data with respect to the corresponding pipes without defects. Fatigue life ratios were calculated between corresponding pipe samples with and without defects. The fatigue life ratio was plotted against the measured magnetic flux leakage intensity, as represented graphically in FIG. 14.

The graph in FIG. 14 shows that actual data obtained during low pressure (LP) testing matched very closely with the low-pressure computer model line 50. Similarly, the graph in FIG. 14 shows that actual data obtained during high-pressure (HP) testing matched very closely with the high-pressure computer model line 52. Thus, the comparison of the testing/validation data with the previously determined correlations between magnetic flux leakage intensity and fatigue life ratio (used for the computer model) indicate computer modeling validity with respect to both low and high pressure conditions. Consequently, the use of algorithm or algorithms 40 for computer modeling via processing system 30 enables an automatic and accurate prediction of fatigue life based on specific pipe defects under both low pressure and high pressure conditions.

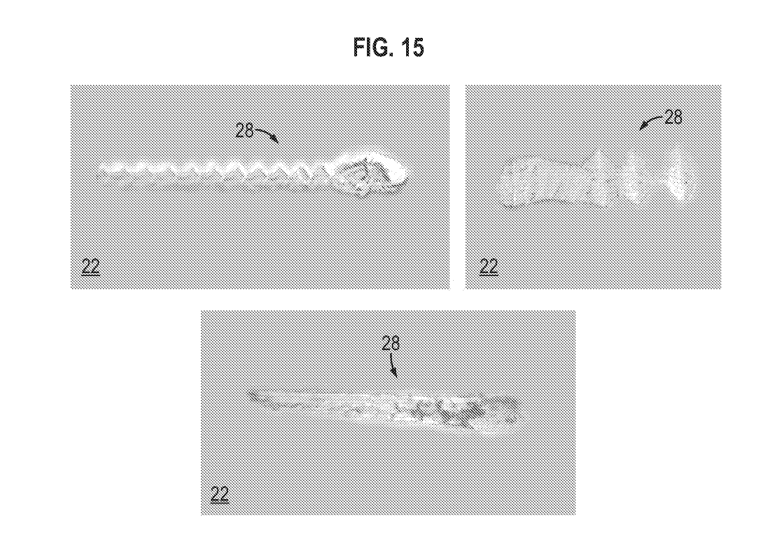

The validated correlations may be used via processing system 30 as part of a computer model for evaluating the severity of defects 28, such as those illustrated in FIG. 15. In this example, the defects 28 illustrated in FIG. 15 were labeled defects 1, 2, 3 and were detected via sensor(s) 24 which, in turn, provided the corresponding magnetic flux leakage data to processing system 30. Using the correlations established in the algorithms/computer models 40 described above, fatigue life ratio was determined to provide an indication of fatigue life as set forth in the table below:

| | Pipe | Pipe | Material | MFL | Fatigue life ratio (ϕ) | |
|---|---|---|---|---|---|---|
| Defect | OD | WT | grade | intensity | LP | HP |
| number | (in.) | (in.) | (ksi) | (μ) | (7% yield) | (40% yield) |
| 1 (FIG. 15, | 1.75 | 0.168 | 80 | 0.12 | 0.37 | 0.66 |
| left) | | | | | | |
| 2 (FIG. 15, | 2.00 | 0.152 | 90 | 0.11 | 0.40 | 0.64 |
| middle) | | | | | | |
| 3 (FIG. 15, | 2.00 | 0.200 | 100 | 0.21 | 0.23 | 0.38 |
| right) | | | | | | |

The methodology described herein provides a model which may be automatically implemented via processing system 30 for determining defect severity and thus predicting fatigue life based on magnetic flux leakage measurements. As described above, computer models 40 may be implemented on processing system 30 and may be based on test data to enable automatic evaluation of coiled tubing 22 or other pipe via magnetic flux leakage detection. In coiled tubing applications, for example, the methodology enables quantification of coiled tubing defect severity to predict a remaining useful life, e.g. fatigue life, of the coiled tubing. After determining the fatigue life, an appropriate action may be selected with respect to the pipe/coiled tubing 22. For example, the pipe/coiled tubing 22 may be pulled from service and discarded, repaired, limited to use for specific operations, or used as normal. The processing system 30 may be programmed to automatically take the appropriate action with respect to the pipe/coiled tubing 22 and/or to output an indicator via output display 38 regarding the appropriate action.

In addition to quantifying coiled tubing defect severity and predicting fatigue life, the methodology also may be used to determine other parameters related to the coiled tubing or other pipe. For example, the methodology may be used to determine a pipe strength and/or pipe pressure rating.

The system and methodologies described herein may be employed in non-well related applications which utilize evaluation of coiled tubing, jointed pipe, and/or other tubing strings. Additionally, processes may employ a variety of sensors, data processing systems, and/or software modules for evaluating sensor data and/or making recommendations. The system may be automated to implement automatic changes to a tubing string operation based on defect data detected and evaluated. In some applications, the operational changes can be made in real time. Additionally, various types of storage databases/libraries may be constructed to accumulate many types of correlations and defect data. The benchmark defect library also may be automatically updated with defect entries based on defects 28 detected during evaluation of pipes, e.g. coiled tubing. Also, elements of the overall processes described herein may be performed at a variety of times and in various orders during implementation of the processes. It is understood that in establishing the correlation between magnetic flux leakage intensity and fatigue life ratio, one method for establishing the correlation is to introduce a bridging/intermediate parameter, such as the geometrical severity parameter (Q) as discussed hereinabove, so that the existing database can be best utilized for remaining fatigue life prediction using MFL measurements. However, the bridging parameter does not have to be the geometrical severity parameter and using another different parameter is still within the scope of the present disclosure. Moreover, a testing program may be carried out to establish a direct correlation between MFL and fatigue life ratio, without resorting to a bridging parameter.

Although a few embodiments of the system and methodology have been described in detail above, those of ordinary skill in the art will readily appreciate that many modifications are possible without materially departing from the teachings of this disclosure. Accordingly, such modifications are intended to be included within the scope of this disclosure as defined in the claims.

What is claimed is:

1. A method for examining a tubing string, comprising:
providing a sensor to monitor a pipe for a magnetic flux leakage signal indicating a defect in the pipe;
outputting data on the magnetic flux leakage signal detected by the sensor to a data processing system;
using correlations between magnetic flux leakage signals and defect severity to automatically predict a fatigue life of the pipe via the data processing system based on the data detected by the sensor; and
selecting an operation with respect to the pipe which is appropriate given the determined fatigue life.

2. The method as recited in claim 1, wherein using comprises using correlations between a magnetic flux leakage intensity and a fatigue life ratio.

3. The method as recited in claim 2, wherein using comprises using an intermediate parameter to construct magnetic flux leakage intensity and the fatigue life ratio relationships.

4. The method as recited in claim 3, wherein using the intermediate parameter comprises using a geometrical severity parameter.

5. The method as recited in claim 1, wherein using comprises identifying the type of defect through defect matching with defects stored in a memory associated with the data processing system.

6. The method as recited in claim 1, wherein using comprises evaluating the fatigue life as a function of the fatigue life of the pipe without the defect.

7. The method as recited in claim 1, wherein providing comprises providing the sensor to monitor coiled tubing.

8. The method as recited in claim 1, wherein selecting comprises using the data processing system to automatically recommend a future action with respect to the pipe.

9. The method as recited in claim 1, further comprising storing data on the correlations between magnetic flux leakage signal and the corresponding type of defect in the defect library.

10. A method, comprising:
using a sensor to monitor coiled tubing for the presence of a magnetic flux leakage signal indicative of a defect in the coiled tubing;
outputting data from the sensor to a data processing system having a processor;
providing the data processing system with correlations between the magnetic flux leakage signal intensity and a fatigue life ratio;
processing the data from the sensor regarding the magnetic flux leakage signal and from a benchmark defect library, via the data processing system, to determine magnetic flux leakage intensity;
predicting a fatigue life based on the corresponding defect severity; and
taking an action with respect to future use of the coiled tubing based on the fatigue life.

11. The method as recited in claim 10, wherein taking the action comprises pulling the coiled tubing from service.

12. The method as recited in claim 10, wherein taking the action comprises repairing the coiled tubing.

13. The method as recited in claim 10, wherein processing the data comprises detecting fatigue life ratio, wherein fatigue life ratio comprises a ratio of fatigue life of a pipe with a defect over fatigue life of the pipe without the defect.

14. The method as recited in claim 10, wherein processing the data comprises using an intermediate parameter to construct magnetic flux leakage intensity and fatigue life ratio relationships.

15. The method as recited in claim 10, further comprising supplementing the benchmark defect library with data obtained during evaluation of coiled tubing.

16. The method as recited in claim 10, wherein using comprises using a plurality of magnetic flux leakage sensors.

17. The method as recited in claim 10, further comprising using the processing system to output data related to fatigue life on a computer display.

18. A system for defect evaluation, comprising:
a sensor positioned along a pipe to monitor for a magnetic flux leakage signal associated with a defect in the pipe; and
a data processing system coupled to the sensor, the data processing system comprising:
a display;
a memory in which a benchmark defect library is stored; and
a processor which uses a computer model to determine correlations between data stored in the benchmark defect library and magnetic flux leakage signals obtained via the sensor to determine a defect severity, the defect severity being associated with a fatigue life which is output to the display.

19. The system as recited in claim 18, wherein the pipe comprises coiled tubing.
